(19) United States
(12) Patent Application Publication
(10) Pub. No.: US 2003/0209198 A1
(43) Pub. Date: Nov. 13, 2003

(54) Method and apparatus for neutralization of ion beam using ac or dc ion source

(76) Inventors: Andrew Shabalin, Fort Collins, CO (US); Colin Quinn, Fort Collins, CO (US); Michael Kishinevski, Manalapa, NJ (US); David S. Lee, Mountain View, CA (US)

Correspondence Address: Benjamin Hudson Jr, Advanced Energy Industries Inc, 1625 Sharp Point Dr, Fort Collins, CO, 80525, US

(21) Appl. No.: 10/181,470

(22) PCT Filed: Jan. 18, 2001
(86) PCT No.: PCT/US01/01760

(51) Int. Cl. C23C 16/00

(52) U.S. Cl. 118/723 R; 118/723 DC

(57) ABSTRACT

There is provided by this invention a unique ion source for depositing thin films on a substrate in a vacuum chamber that neutralizes the positive electric charges that develop on the substrate and vacuum chamber apparatus that may cause arcing and degradation of the film deposition. A power supply with a reversing voltage waveform is utilized that neutralizes the electric charge on the substrate and the vacuum chamber apparatus. A pulsed operation can be used that is applicable to a low voltage mode of the source wherein current may not be limited by the discharge voltage so average current cant be kept high by increasing peak current during the duty cycle. Also, in the high voltage mode neutralization can be achieved with no significant loss of ion beam etch rate despite a shortened duty cycle.

There is also provided by this invention another embodiment wherein the ion source is comprised of a second power supply which applies a negative dc bias. In this embodiment the discharge power supply has its positive output terminal connected to the anode of the ion source and the negative output terminal to the cathode. The second bias power supply can have its positive output terminal connected to the vacuum chamber and a negative output terminal to the cathode of the ion source.

### BACKGROUND OF THE INVENTION

1. Field of the Invention

Generally, the invention pertains to the field of vacuum thin film deposition onto substrates using ion sources and modifying properties of substrates by ion beam treatment. Specifically, the invention focuses upon a new and improved method and apparatus for providing the supply of electrons onto a thin film substrate for neutralization of electric charge brought onto the surface of said substrate and other surfaces of the apparatus by the ion beam radiating from a closed drift ion source.

2. Description of the Prior Art

When a substrate is exposed to an ion beam, a need arises to close the electrical current path, or in another words to neutralize the electrical charge brought with the ions onto the substrate surface as well as onto other surfaces of the apparatus. This need is especially apparent for insulating substrates, but even conductive substrates as well as other surfaces of the apparatus frequently have poorly conducting inclusions or thin films on them. If those films or inclusions are not discharged, the accumulated charge may lead to an electrical breakdown and an onset of an arc that may introduce defects at the substrate surface. Although similar charging problems exist in other vacuum processing fields, such as in reactive magnetron sputtering, the ion beam processing is an entirely different technology. It operates on different principles, at different voltage levels, different polarities, and even with charged particles hitting different surfaces and so is not thought of as analogous. Ion beam etching of silicon oxide is one example of an ion beam process that is addressed by present invention. The invention specifically pertains to closed drift ion sources, such as the LIS and MCIS series manufactured by Advanced Energy Industries of Fort Collins, Colo. These closed drift ion sources are quickly finding new applications due to their rugged design and low maintenance. Solving neutralization problems for these sources opens markets for these types of supplies.

Most ion sources incorporate some kind of an electron emitter device, commonly referred to as a neutralizer to supply electrons onto a substrate surface as taught, for instance, in a reference book, entitled “Handbook of Ion Beam Processing Technology” edited by Jerome J. Cuomo, Stephen M. Rossnagel and Harold R. Kaufman (Noyes Publications), hereby incorporated by reference. The electron emitter frequently doubles as a neutralization device, or a second emitter sometimes is used specifically for neutralization.

Two basic types of electron emitters are being commonly used, a hot filament and a hollow cathode. A significant problem with the use of hot filament thermionic electron emitters is that the operational lifetime of the emitters can be very limited, often less than 100 hours. This may be especially true when reactive gases, such as oxygen, are present in the ion source. Similarly, hollow cathode electron emitters can have a lifetime of about 1000 hours as disclosed by U.S. Pat. Nos. 3,156,090; 3,913,320; 3,952,228; 3,956,666; and 3,969,646, each hereby incorporated by reference. An additional problem with an electron emitter neutralizer is that it can introduce additional complexity to the system, and perhaps, a need to align the position of the neutralizer so that it has good coupling with the plasma but does not stand in the way of the ion beam. Yet another additional problem with an electron emitter neutralizer can be a non-uniformity that it may introduce onto the process, especially with wide aperture beams. To mitigate this non-uniformity several neutralizers have sometimes been used.

Closed-drift ion sources, like the LIS series and the MCIS series manufactured by Advanced Energy Industries of Fort Collins Colo., do not require an electron emitter for their operation. This can greatly expand the application range by making the source design reliable and rugged and having long maintenance-free operation time. However, in certain thin film applications that are not tolerant to ion beam charging there can be a great need for a way to neutralize the substrate surface without compromising the advantages of the ion source design.

For grid ion sources a different method of thin film neutralization, not requiring a hot electron emitter, was proposed by D. Korzec, T. Kebler, H. M. Keller and J. Engelmann in “Filamentless Neutralization of Broad Ion Beams”, in the Journal of Vacuum Science and Technology, B9 (1991), pgs 3084-3089. According to this publication, a bipolar pulsing of grid voltages can make the ion source work as an electron source during the reverse polarity part of every pulse. Since thin films can have high capacitance, the voltage on the surface may not change significantly during the pulse so the film surface can be kept at low potential if the pulse frequency is high enough. This method did not seem to be applicable to closed drift ion sources because a closed drift source cannot sustain its discharge with reversed bias voltage. The reason for this is that magnetic field lines in the closed drift ion source usually must have both ends terminating at the cathode so electrons cannot arrive from cathode to anode along magnetic the field line. However, almost always all magnetic field lines originating at the anode terminate at the cathode, so reverse bias could force electrons to the positive side of the source before they can make any ionization. Moreover, a shortened duty cycle appeared to cause reduction of the ion source throughput and this alone could make this method commercially unattractive.

### SUMMARY OF THE INVENTION

The present invention applies a new technique to power a closed drift ion source, based on an assumption that the ion source and ion beam plasma produced by the ion source during the positive part of the power supply waveform will exist for sometime after the application of a reverse voltage and thus allow electron current to sustain during the reverse polarity cycle long enough to neutralize the substrate. As far as duty cycle-limited throughput, in one embodiment the present invention can use a pulsed operation as particularly applicable to the low-voltage mode of the source where current may not be limited by discharge voltage so average current can be kept high by increasing peak current during the duty cycle. Indeed, experiments have demonstrated these assumptions to be correct. Moreover, in another embodiment, the technique is applied to the high voltage mode as well, and neutralization can now be achieved with no significant loss of ion beam etch rate despite a shortened duty cycle. This exists because with a pulse power supply, a stable high voltage mode operating region can now extend toward higher gas flow thus allowing a sustained higher average ion current.

In addition, the present invention addresses the need for neutralization by applying negative bias to the cathode of the ion source. In this design a negative DC bias is supplied by a second power supply. The discharge power supply has its positive output terminal connected to the anode of the ion source and the negative output terminal to the cathode. The second bias power supply can have its positive output terminal connected to the vacuum chamber and a negative output terminal to the cathode of the ion source. This design of the ion source can be changed so that the cathode is electrically insulated from the vacuum chamber. A negative electrical bias can be applied to the cathode relative to the ground at a level of anywhere from 1% to 99% of the discharge voltage of the ion source. Our experiments have shown that substrate charge is essentially eliminated when the bias voltage exceeds a certain threshold. The threshold voltage may depend on process parameters, such as gas composition, pressure, substrate material, etc.

The present invention while alleviating the above mentioned problems does not reduce the existing range of ion source applications. On the contrary, it expands the range of application of ion beams by making the apparatus compatible with wider selection of gases, by making the ion beam system much more robust and reliable, by greatly extending operational lifetime and by reducing maintenance. Moreover, according to the present invention, the power supply for pulsed operation can be less expensive even than a regular DC power supply, and certainly much less expensive than a power supply system used with conventional neutralization techniques that requires a separate power supply for the neutralizer. The power supply cost reduction can further expand the range of commercial applications of closed drift ion sources.

### BRIEF DESCRIPTION OF THE DRAWINGS

FIG. 1 shows examples of ion power supply output voltage waveforms that can be used in the present invention;

FIG. 2 shows a preferred embodiment applied to a closed drift ion source, such as the LIS series manufactured by Advanced Energy Industries. The power supply polarity shown is during the working segment of the waveform;

FIG. 3 shows an example of schematics to produce a self-biased sine waveform; and

FIG. 4 shows an example of one embodiment with an electrical bias as applied to a closed drift ion source such as the LIS or SCIS series manufactured by Advanced Energy Industries.

### DETAILED DESCRIPTION OF THE PREFERRED EMBODIMENTS

In one embodiment, the present invention uses the conductivity of a transient glow plasma that accompanies the ion beam in the vacuum chamber to neutralize positive electrical charge on a substrate and other apparatus surfaces. To accomplish that, a special ion source power supply is used that periodically reverses the polarity for a segment of time, biasing all or some parts of the ion source negatively relative to the substrate and the vacuum chamber. During this reverse bias cycle the plasma potential swings toward negative polarity and this can allow electrons from the plasma to reach surfaces that need to be neutralized.

Although relying upon fundamentally different principles, problems addressed in the field of magnetron sputtering can illustrate some of the advantages now available in the field of ion beam processing such as in closed drift ion sources, among others. In magnetron sputtering apparatus arcing was a severe problem that limited the throughput and reduced quality of the product, especially during reactive sputtering when sputtered cathode material reacts with reactive gas in the vacuum chamber, such as oxygen to produce dielectric films on the substrate. The arcing was greatly reduced or eliminated by using a pulsed DC power supply, such as in U.S. Pat. No. 5,427,669 by Drummond of Advanced Energy Industries, Inc., hereby incorporated by reference. Unlike a magnetron application, an ion source apparatus according to the present invention has a completely different polarity, among other differences. While in the magnetron film deposition apparatus a magnetron cathode is biased negatively during the active part of the cycle and positive during the neutralization part of the cycle, in the ion source apparatus the power supply polarity is inverse, because ion acceleration requires positive voltage on the ion source anode, and neutralization occurs when output voltage is negative. The commercial advantages, however, can be just as significant in this field.

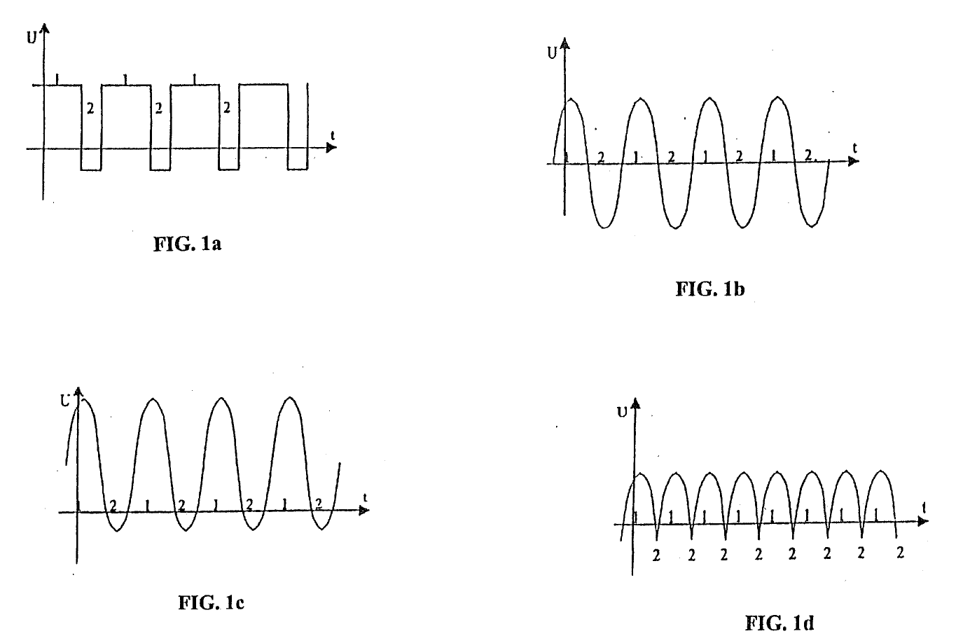

A variety of power supply voltage waveforms can be used in the present invention, depending on needs and cost constraints of particular applications. A necessary base frequency of the waveform depends again on the particular application but is generally either in the medium frequency range, from several hundred Hertz to several megahertz. In applications that require narrow ion energy distribution, rectangular pulses can be used as shown on FIG. 1a, as it would not usually widen the ion energy spread. In another application, the power supply output can be a sine wave (FIG. 1b), a combination of a sine wave with DC (FIG. 1c), a negatively biased rectified sine wave (FIG. 1d), etc. As explained above, the duty cycle of the ion beam is during the positive voltage segment (1), and neutralization is accomplished during the reverse bias segment (2). It is to be understood that the voltage waveforms shown on FIGS. 1a through 1d are idealized waveforms that are close to voltage waveforms that power supplies produce with a resistive test load. When connected to the ion source, the voltage waveform may be distorted by nonlinear impedance of the ion source and could depend on ion source operational parameters and on output impedance of the power supply.

Furthermore, the frequency of the bias reverse pulses may be in the range of a few kilohertz to a few megahertz, depending on particular application needs and available power supply technology. The low frequency limit may also be determined by two important considerations. The first may be the decay time of the transient plasma in and around the ion source. Experimentally it appears that this time is in the range of several microseconds, so for the technique to keep high throughput, it appears that the frequency should not go below 100 kHz or so. Another consideration may be the thickness of the isolating film. The voltage to which the surface charges is often equal to Jt/C where J is the ion current density, t is duty cycle and C is capacitance of the film per unit area. The thicker the insulating film, the lower the capacitance, and thus the higher peak voltage a film surface might reach. This can mean that the frequency may be selected as higher for thicker films or thicker insulating substrates. In addition, the high frequency limit could be determined by optimal power supply cost versus frequency. For example, it is anticipated that 400 to 600 kHz is the most preferable frequency range for film thicknesses in the range of thousands of Angstroms.

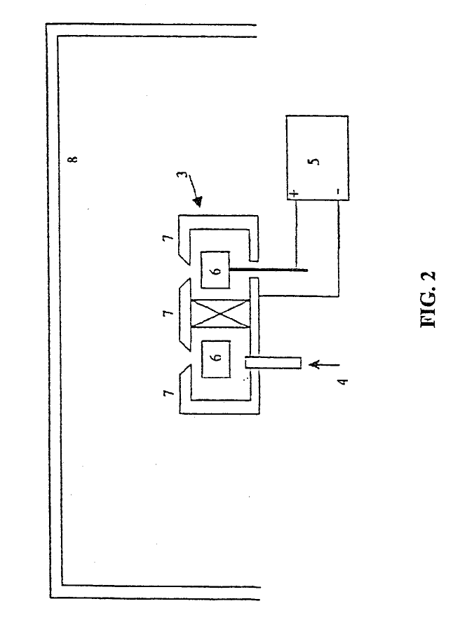

Another preferred embodiment is schematically shown on FIG. 2. A closed drift ion source (3), such as the MCIS series manufactured by Advanced Energy Industries is used in this embodiment. The power supply (5) has one output terminal connected to the anode (6) of the ion source and the other output terminal to the cathode (7) or to the vacuum chamber (8). As discussed above, a variety of output waveforms can be used. Accordingly, said power supply can be of but not limited to one of the following types:

A sine wave medium frequency power supply can be used, such as the PE-II manufactured by Advanced Energy Industries.

A pulsed DC power supply can be used, such as Advanced Energy's Pinnacle Plus.

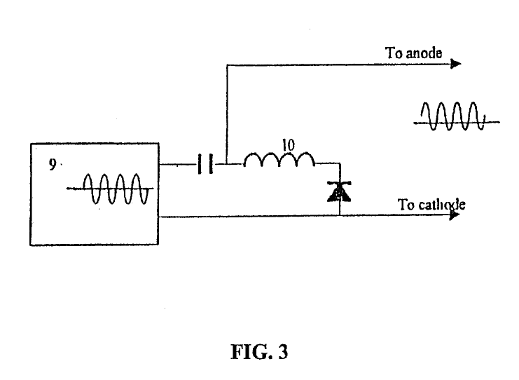

A DC biased sine wave power supply can also be used. One way to produce a self-biased sine waveform can be schematically shown in FIG. 3 using, for example, the output of Advanced Energy's PE-II (9). The value of inductor (10) in the range of several microhenry to several millihenry can determine the magnitude of DC self bias.

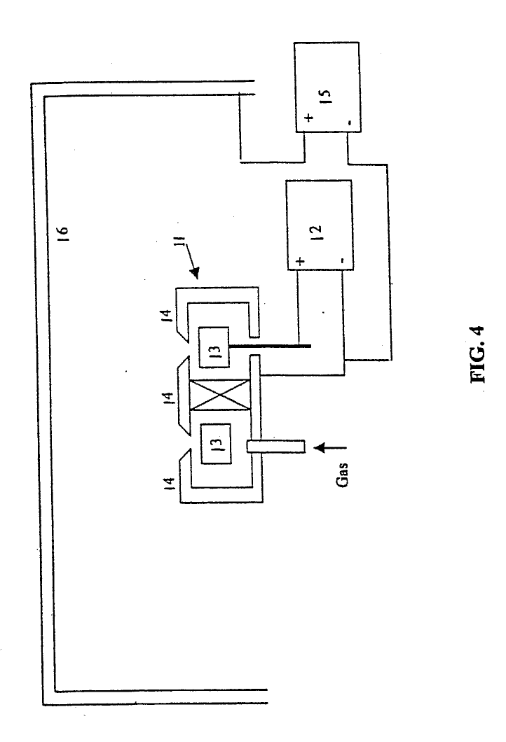

As mentioned earlier, one embodiment of the present invention can address the neutralization problem by applying a negative bias to the cathode of the ion source. This is shown schematically in FIG. 4. In this embodiment, a closed drift ion source (11), such as an MCIS, or LIS, or SCIS series manufactured by Advanced Energy Industries can be used. The discharge power supply (12) may have a positive output terminal connected to the anode (13) of the ion source and the negative output terminal to the cathode (14). The bias power supply (15) can have its positive output terminal connected to the vacuum chamber (16), and a negative output terminal to the cathode of the ion source (14). As one of ordinary skill in the art would readily understand, clearly there are different ways of wiring such power supplies, but the net result should be that the cathode is biased negatively relative to the ground and the anode is biased positively relative to the cathode. Further, both power supplies can be of direct current type, and it may also be desirable that both power supplies have arc control circuitry, such as the Pinnacle manufactured by Advanced Energy of Fort Collins, Colo.

We have found that this neutralization technique works in a wide range of operational parameters of a closed drift ion source. As examples for comparison, the following parameters were tested in one system type:

### EXAMPLE 1

(biased)

Source Type: MCIS (multi cell ion source) such as from Advanced Energy Industries, Inc.

| | |
|---|---|
| Anode Voltage: | 1500 volts (to ground) |
| Anode Current: | 0.22 A |
| Cathode Voltage: | −170 volts (to ground) |
| Cathode Current: | 0.3 A |
| Floating Potential: | 0.4 volts (of substrate) |
| Gas Composition: | Argon |
| Gas Flow Rate: | 25 sccm |
| Pumping Speed: | 400 L/sec |
| Magnet Current: | 1.25 A |

### EXAMPLE 2

(unbiased)

Source Type: MCIS (multi cell ion source) such as from Advanced Energy Industries, Inc.

| | |
|---|---|
| Anode Voltage: | 1500 volts (to ground) |
| Anode Current: | 0.11 A |
| Cathode Voltage: | −0 volts (to ground) |
| Cathode Current: | 0.06 A |
| Floating Potential: | 100 volts (of substrate) |
| Gas Composition: | Argon |
| Gas Flow Rate: | 25 sccm |
| Pumping Speed: | 400 L/sec |
| Magnet Current: | 1.25 A |

As to these parameters, it should be understood that they may represent absolute values, relative values based upon another parameter, or even just one list which was shown to perform well. They are not to be considered as limiting, of course.

It is to be understood that the scope of present invention is not limited to particular ion sources, but can work with a wide variety of ion sources. Further, as can be easily understood from the foregoing, the basic concepts of the present invention may be embodied in a variety of ways. It involves both closed drift ion source neutralization techniques, and closed drift ion source power supply techniques, as well as devices to accomplish the appropriate power supply arrangements. In this application, the neutralization techniques are disclosed as part of the results shown to be achieved by the various devices described and as steps which are inherent to utilization. They are simply the natural result of utilizing the devices as intended and described. In addition, while some devices are disclosed, it should be understood that these not only accomplish certain methods but also can be varied in a number of ways. Importantly, as to all of the foregoing, all of these facets should be understood to be encompassed by this disclosure.

Further, each of the various elements of the invention and claims may also be achieved in a variety of manners. This disclosure should be understood to encompass each such variation, be it a variation of an embodiment of any apparatus embodiment, a method or process embodiment, or even merely a variation of any element of these. Particularly, it should be understood that as the disclosure relates to elements of the invention, the words for each element may be expressed by equivalent apparatus terms or method terms—even if only the function or result is the same. Any patents, publications, or other references mentioned in this application for patent, as well as all references listed in the list of References to be Incorporated by Reference in Accordance with the Provisional Patent, or other information statement filed with the application are hereby incorporated by reference. However, to the extent that such information or statements incorporated by reference might be considered inconsistent with the patenting of this/these invention(s) such statements are expressly not to be considered as made by the applicant(s).

Thus, the applicant(s) should be understood to claim at least: i) each of the pulse devices as herein disclosed and described, ii) the related methods disclosed and described, iii) similar, to equivalent, and even implicit variations of each of these devices and methods, iv) those alternative designs which accomplish each of the functions shown as are disclosed and described, v) those alternative designs and methods which accomplish each of the functions shown as are implicit to accomplish that which is disclosed and described, vi) each feature, component, and step shown as separate and independent inventions, vii) the applications enhanced by the various systems or components disclosed, viii) the resulting products produced by such systems or components, and ix) methods and apparatuses substantially as described hereinbefore and with reference to any of the accompanying examples, and x) the various combinations and permutations of each of the elements disclosed.

We claim:

1. A closed drift ion source for depositing a thin film on a substrate in a vacuum chamber, comprising:
a metallic housing;
a gas input into the housing for receiving a reactive gas;
a magnetic field generating means for producing a magnetic field within the housing;
at least one magnetic gap in the housing wherein the opposite sides of the magnetic gap define a cathode of the ion source;
at least one anode in the housing in close proximity to the magnetic gap; and a power supply having a first terminal connected to the cathode and a second terminal connected to the cathode to supply a voltage waveform that periodically reverses the polarity of the first and second terminals wherein positive electric charges on a substrate in the vacuum chamber, the metallic housing, and vacuum chamber apparatus are neutralized.

2. A closed drift ion source for depositing a thin film on a substrate in a vacuum chamber as recited in claim 1 the voltage waveform is a rectangular pulse.

3. A closed drift ion source for depositing a thin film on a substrate in a vacuum chamber as recited in claim 1 the voltage waveform is a sine wave.

4. A closed drift ion source for depositing a thin film on a substrate in a vacuum chamber as recited in claim 1 the voltage waveform is a sine wave with DC.

5. A closed drift ion source for depositing a thin film on a substrate in a vacuum chamber as recited in claim 1 the voltage waveform is a negatively biased rectified sine wave.

6. A closed drift ion source for depositing a thin film on a substrate in a vacuum chamber, comprising:
a metallic housing;
a gas input into the housing for receiving a reactive gas;
a magnetic field generating means for producing a magnetic field within the housing;
at least one magnetic gap in the housing wherein the opposite sides of the magnetic gap define a cathode of the ion source;
at least one anode in the housing in close proximity to the magnetic gap; and a power supply having a first terminal capacitively connected to the anode, a second terminal directly connected to the cathode, and an inductance in series with a diode connected between the anode and cathode wherein a self-biased sine wave form is produced that periodically reverses the polarity of the first and second terminals wherein positive electric charges on a substrate in the vacuum chamber, the metallic housing, and vacuum chamber apparatus are neutralized.

7. A closed drift ion source for depositing a thin film on a substrate in a vacuum chamber, comprising:
a metallic housing;
a gas input into the housing for receiving a reactive gas;
a magnetic field generating means for producing a magnetic field within the housing;
at least one magnetic gap in the housing wherein the opposite sides of the magnetic gap define a cathode of the ion source;
at least one anode in the housing in close proximity to the magnetic gap; and a bias power supply having its positive output terminal connected to the vacuum chamber housing and its negative output terminal connected to the cathode of the ion source; and a second power supply having a first terminal connected to the cathode and a second terminal connected to the cathode to supply a voltage waveform that periodically reverses the polarity of the first and second terminals wherein positive electric charges on a substrate in the vacuum chamber, the metallic housing, and vacuum chamber apparatus are neutralized.

8. A closed drift ion source for depositing a thin film on a substrate in a vacuum chamber as recited in claim 7 the voltage waveform is a rectangular pulse.

9. A closed drift ion source for depositing a thin film on a substrate in a vacuum chamber as recited in claim 7 the voltage waveform is a sine wave.

10. A closed drift ion source for depositing a thin film on a substrate in a vacuum chamber as recited in claim 7 the voltage waveform is a sine wave with DC.

11. A closed drift ion source for depositing a thin film on a substrate in a vacuum chamber as recited in claim 7 the voltage waveform is a negatively biased rectified sine wave.
